(19) United States
(12) Patent Application Publication
(10) Pub. No.: US 2009/0224314 A1
(43) Pub. Date: Sep. 10, 2009

(54) SEMICONDUCTOR DEVICE AND THE METHOD OF MANUFACTURING THE SAME

(75) Inventor: Mutsumi KITAMURA, Matsumoto City (JP)

Correspondence Address: ROSSI, KIMMS & McDOWELL LLP., 20609 Gordon Park Square, Suite 150, Ashburn, VA, 20147, US

(73) Assignee: FUJI ELECTRIC DEVICE TECHNOLOGY CO., LTD., Tokyo (JP)

(21) Appl. No.: 12/401,257

(22) Filed: Mar. 10, 2009

(30) Foreign Application Priority Data
Mar. 10, 2008 (JP) 2008-058898

(51) Int. Cl. H01L 29/78; H01L 21/336

(52) U.S. Cl. 257/330; 438/270; 257/E29.257; 257/E21.419

(57) ABSTRACT

A power MOSFET exhibits a high breakdown voltage and low ON-state resistance. The device includes a trench formed in a semiconductor substrate, a gate electrode located along a side wall of the trench and a bottom wall of the trench near a side wall thereof, a pillar section, a first drain region of a first conductivity type in the pillar section, a base region of a second conductivity type in contact with the side wall of the trench in a bottom portion thereof and the bottom wall of the trench, a source region of the first conductivity type in a surface portion of the base region, a RESURF region of the second conductivity type in the pillar section, the RESURF region being formed in contact with the first drain region; and a second drain region of the first conductivity type in a side wall surface portion of the pillar section.

### BACKGROUND

The present invention relates to power MOSFETs and such semiconductor devices used in power supply ICs, motor driving ICs for driving a motor and such power ICs. It is required for the power MOSFETs and such semiconductor devices to exhibit low ON-state resistance and a high breakdown voltage and to perform high-speed switching. The present invention relates also to the method of manufacturing the power MOSFETs and such semiconductor devices described above.

It is usually required for power MOSFETs incorporated in a power supply IC to exhibit low ON-state resistance and to perform high-speed switching. Moreover, when an input voltage is high, it is required for the power MOSFETs to exhibit a high breakdown voltage. The power MOSFETs, which facilitate obtaining a high breakdown voltage and low ON-state resistance, include a trench lateral power MOSFET (hereinafter referred to as a “TLPM”).

FIG. 13 is a cross sectional view of a conventional TLPM. FIG. 13 shows a half cell that constitutes a TLPM. The cross section shown in FIG. 13 corresponds to an A-section in FIG. 11. Referring to FIG. 13, the conventional TLPM includes a p-type semiconductor substrate 1, n-type well region 2 on p-type semiconductor substrate 1, n-type drain region 3a on n-type well region 2, and p-type base region 12 on n-type well region 2. The conventional TLPM also includes first trench 6 and second trench 11. First trench 6 is arranged such that first trench 6 is in contact with n-type drain region 3a in the surface portion of n-type well region 2. Second trench 11, the opening thereof is smaller than the opening of first trench 6, is in contact with first trench 6. Since FIG. 13 shows a half cell, the right-hand-side half of pillar section 30 is shown in FIG. 13. The left-hand-side half of first trench 6 and the left-hand-side half of second trench 11 are shown in FIG. 1 3. In practice, there exist first trench 6 and second trench 11 on the left hand side of pillar section 30.

The conventional TLPM further includes n-type source region 15 arranged on p-type base region 12 and extended to second trench 11 through the bottom wall of second trench 11, gate insulator film 13 arranged on the side wall and the bottom wall of second trench 11, thick insulator film 10 arranged on the side wall of first trench 6, gate electrode 14 arranged on gate insulator film 13 and thick insulator film 10, and an insulator film (e.g. an oxide film) arranged on gate electrode 14 and n-type drain region 3a and filling first and second trenches 6 and 11.

Moreover, the conventional TLPM includes interlayer insulator film 16 formed of not-shown first trench mask oxide film 5 (cf. FIG. 10) and not-shown insulator film 16a (cf. FIG. 10), wolfram plugs 20 and 21 filling the contact holes formed through interlayer insulator film 16 and in contact with n-type drain region 3a and n-type source region 15 via n-type contact regions 18 and 19 respectively, drain metal wiring 22 connected to wolfram plug 20, and source metal wiring 23 connected to wolfram plug 21.

The conventional TLPM, in which gate electrode 14 is formed on the trench side wall and n-type drain region 3a is formed in pillar section 30, that is the portion of the semiconductor substrate sandwiched between the trenches, facilitates narrowing the device pitch and reducing the ON-state resistance per a unit area while keeping a high breakdown voltage. Pillar section 30 is the portion of the semiconductor substrate between a plurality of the trenches formed as described above (the portion of the semiconductor substrate on the left hand side of the trenches in FIG. 13). In detail, pillar section 30 is the portion of the semiconductor substrate sandwiched between a pair of first and second trenches 6 and 11 and a pair of first and second trenches 6 and 11. The pillar section is called the “trench pillar” sometimes.

Japanese Unexamined Patent Application Publication No. 2004-253576 discloses a method of manufacturing the semiconductor device as described above. The method forms a recess such as a trench in the surface portion of a semiconductor layer, and then rounds the corner portion of the recess, which will be the boundary between the side wall and the bottom wall of the recess, by isotropic dry etching.

Japanese Unexamined Patent Application Publication No. Hei. 06 (1994)-224438 discloses a MOS semiconductor device that includes a gate region formed in the depth direction of a trench (vertically along the trench) so as not to widen the channel region of a transistor horizontally but to narrow the device region.

Japanese Unexamined Patent Application Publication No. 2002-184980 discloses a method that secures insulation between two kinds of electrodes formed in a trench in a TLPM and obviates the problem caused by the device breakdown voltage that depends on the distance from the substrate contact.

Japanese Unexamined Patent Application Publication No. Hei. 08 (1996)-181313, and related counterpart U.S. Pat. No. 5,701,026 A, discloses a trench lateral MISFET, the uniformity of the gate insulator film thereof is excellent, the reliability thereof is high, the ON-state resistance thereof is low, and the tradeoff relation between the breakdown voltage and the ON-state resistance thereof is excellent.

Japanese Unexamined Patent Application Publication No. 2005-197287, and related counterpart U.S. Patent Application Publication No. US 2007/0080399 A1, discloses a super junction structure, arranged in the pillar section in a trench vertical MOSFET, that improves the breakdown voltage of the trench vertical MOSFET.

Japanese Unexamined Patent Application Publication No. 2006-74015, and related counterpart U.S. Patent Application Publication No. US 2006/0027861 A1, discloses a drift layer and a reduced-surface-electric-field layer (hereinafter referred to as a “RESURF layer”), arranged vertically in the pillar section in a trench vertical MOSFET, which facilitate reducing the device size and the ON-state resistance of the trench vertical MOSFET.

In the conventional TLPM shown in FIG. 13, thick insulator film 10 formed on the side wall of first trench 6 works for a field plate for electric field relaxation. For improving the breakdown voltage, it is necessary to dope n-type drain region 3a more lightly. However, since n-type drain region 3a works also for a drift region, lightly doped n-type drain region 3a causes high ON-state resistance. The above references do not describe anything on the formation of a RESURF structure in the pillar section in the TLPM structure for improving the tradeoff relation between the breakdown voltage and the ON-state resistance thereof.

In view of the foregoing, it would be desirable to obviate the problems described above. It would be also desirable to provide a TLPM and such a semiconductor device that exhibits a high breakdown voltage and low ON-state resistance and improves the tradeoff relation between the breakdown voltage and the ON-state resistance.

### SUMMARY OF THE INVENTION

The invention provides a TLPM and such a semiconductor device that exhibits a high breakdown voltage and low ON-state resistance and with an improved tradeoff relationship between the breakdown voltage and the ON-state resistance.

According to a first aspect of the invention, a semiconductor device includes a semiconductor substrate, a trench, a plurality of the trenches being formed from the surface of the semiconductor substrate to the inside thereof, a gate electrode along the side wall of the trench and the bottom wall of the trench near the side wall thereof with a gate insulator film interposed between the gate electrode and the side wall and bottom wall of the trench, pillar section, the pillar section being the section of the semiconductor substrate sandwiched between the trenches, a first drain region of a first conductivity type in the pillar section, a base region of a second conductivity type in contact with the side wall of the trench in the bottom portion thereof and the bottom wall of the trench, a source region of the first conductivity type in the surface portion of the base region, the source region being extended to the trench through the bottom wall thereof, a RESURF region of the second conductivity type in the pillar section, the RESURF region being in the first drain region or in contact with the lower surface of the first drain region, and a second drain region of the first conductivity type in the side wall surface portion of the pillar section, the second drain region being in contact with the first drain region, the base region and the RESURF region. Advantageously, the trench preferably has an upper opening widened; and the semiconductor device further includes a thick oxide film interposed between the trench widened and the gate electrode.

According to a second aspect of the invention, there is provided a method of manufacturing the semiconductor device described above, the method including forming the second drain region by the tilt angle ion implantation of an impurity of the first conductivity type. According to the invention, a thick oxide film is formed locally on the pillar section, which is the section of the semiconductor substrate sandwiched between the trenches. By making the thick oxide film work for a field plate, a high breakdown voltage is obtained. Further, by forming a second n-type drain region on the side wall of a p-type region formed in the pillar section, the p-type region is made to work for a p-type RESURF region that relaxes the electric field.

Due to the structure described above, a high breakdown voltage is obtained even if the second n-type drain region is doped more heavily. Therefore, by doping the second drift region more heavily, the ON-state resistance is reduced with no problem. In other words, the thick oxide film and the p-type RESURF region facilitate improving the tradeoff relation between the breakdown voltage and the ON-state resistance and obtaining a semiconductor device that exhibits a high breakdown voltage and low ON-state resistance.

Other features, objectives, advantages and embodiments of the invention will become apparent to those skilled in art from the following detailed description of the preferred embodiments of the invention and the accompanying drawings.

### BRIEF DESCRIPTION OF THE DRAWINGS

The invention will be described with reference to certain preferred embodiments thereof and the accompanying figures, wherein:

FIG. 1 is a cross sectional view of a semiconductor device according to a first embodiment of the invention;

FIG. 2 is a cross sectional view of a semiconductor device according to a second embodiment of the invention;

FIG. 3 is a cross sectional view of a semiconductor device according to a third embodiment of the invention;

FIG. 4 is a cross sectional view of a semiconductor device according to a fourth embodiment of the invention;

FIG. 5 is a cross sectional view describing a manufacturing step in a manufacturing method according to a fifth embodiment of the invention for manufacturing a semiconductor device;

FIG. 6 is a cross sectional view describing a manufacturing step subsequent to the manufacturing step described with reference to FIG. 5;

FIG. 7 is a cross sectional view describing a manufacturing step subsequent to the manufacturing step described with reference to FIG. 6;

FIG. 8 is a cross sectional view describing a manufacturing step subsequent to the manufacturing step described with reference to FIG. 7;

FIG. 9 is a cross sectional view describing a manufacturing step subsequent to the manufacturing step described with reference to FIG. 8;

FIG. 10 is a cross sectional view describing a manufacturing step subsequent to the manufacturing step described with reference to FIG. 9;

FIG. 11 is a cross sectional view describing a manufacturing step subsequent to the manufacturing step described with reference to FIG. 10;

FIG. 12 shows an impurity concentration distribution profile in the semiconductor device shown in FIG. 1; and.

FIG. 13 is a cross sectional view of a conventional TLPM.

### DETAILED DESCRIPTION OF THE PREFERRED EMBODIMENTS

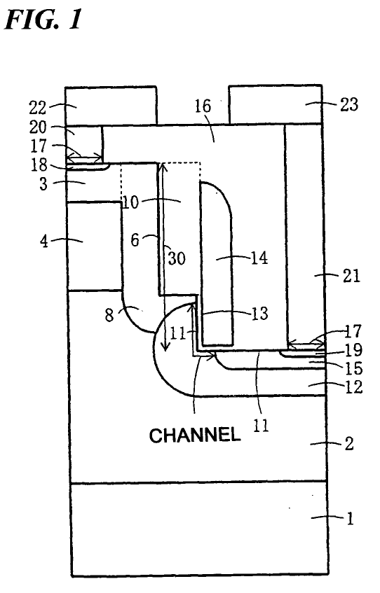

FIG. 1 is a cross sectional view of a semiconductor device according to a first embodiment of the invention. Exemplary, the semiconductor device according to the first embodiment is a high-side N-channel MOSFET having a TLPM structure. The high-side N-channel MOSFET is a MOSFET, in which an N-channel MOSFET structure is formed in n-type well region 2 formed in the surface portion of p-type semiconductor substrate 1. In the high-side N-channel MOSFET, n-type well region 2 can be biased at an arbitrary potential higher than the potential of p-type semiconductor substrate 1. Therefore, the N-channel MOSFET structure in n-type well region 2 biased at a high potential facilitates making the source region thereof operate not at the ground potential but at an arbitrary high potential. Therefore, the MOSFET described above is called a “high-side MOSFET”.

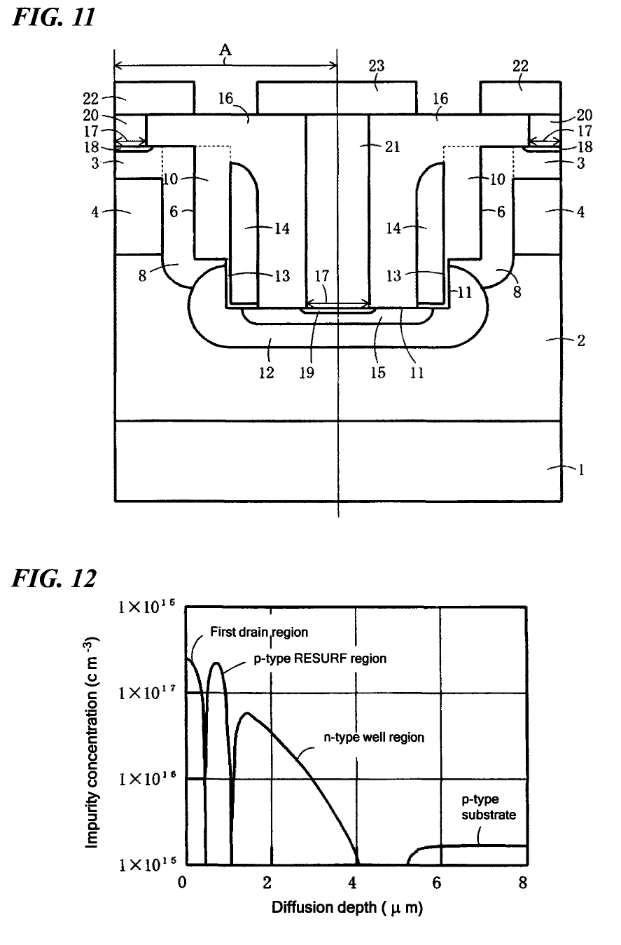

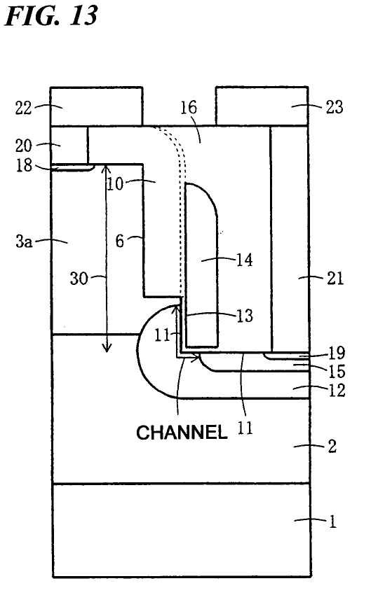

FIG. 1 shows a half cell that constitute a TLPM. The cross section shown in FIG. 1 corresponds to an A-section in FIG. 11 that shows an entire cell. The high-side N-channel MOSFET includes p-type semiconductor substrate 1, n-type well region 2 arranged on p-type semiconductor substrate 1, p-type RESURF region 4 and p-type base region 12 arranged on n-type well region 2, and first n-type drain region 3 arranged on p-type RESURF region 4. The high-side N-channel MOSFET also includes a trench formed of a first trench 6 and second trench 11. First trench 6 is in contact with first n-type drain region 3, p-type RESURF region 4, and n-type well region 2 in the surface portion of n-type well region 2. Second trench 11, the opening thereof is smaller than the opening of first trench 6, is in contact with first trench 6. Since FIG. 1 shows half a cell, the right-hand-side half of pillar section 30 is shown in FIG. 1. The left-hand-side half of first trench 6 and the left-hand-side half of second trench 11 are shown in FIG. 1. Although not illustrated, there exists first trench 6 and second trench 11 on the left hand side of pillar section 30 in practice.

The high-side N-channel MOSFET further includes second n-type drain region (n-type drain drift region) 8 and n-type source region 15. Second n-type drain region 8 is in contact with first n-type drain region 3, p-type RESURF region 4, n-type well region 2, and p-type base region 12. Second n-type drain region 8 is extended to first trench 6 through the side wall and bottom wall of first trench 6. The n-type source region 15 is arranged in the surface portion of p-type base region 12 and extended to second trench 11 through the bottom wall of second trench 11.

Furthermore, the high-side N-channel MOSFET includes gate insulator film 13 arranged on the side wall and the bottom wall of second trench 11, thick insulator film 10 arranged on the side wall of first trench 6, gate electrode 14 arranged on gate insulator film 13 and thick insulator film 10, and insulator film 16a arranged on gate electrode 14 and first n-type drain region 3 and filling first and second trenches 6 and 11.

Moreover, the high-side N-channel MOSFET includes interlayer insulator film 16 formed of first trench mask oxide film 5 and insulator film 16a, contact holes 17 formed through interlayer insulator film 16, first n-type contact region 18 and second n-type source region 19 formed in the surface portions of first n-type drain region 3 and n-type source region 15, respectively, using contact holes 17 as masks, wolfram plugs 20 and 21 filling contact holes 17 and in contact with first and second contact regions 18 and 19, drain metal wiring 22 connected to wolfram plug 20, and source metal wiring 23 connected to wolfram plug 21. Insulator film 16a and first trench mask oxide film 5 will be described later in connection with the manufacturing steps for manufacturing the semiconductor device according to the invention.

Second trench 11, the opening thereof is smaller than the opening of first trench 6, is formed in the bottom portion of first trench 6. In the surface portion of p-type base region 12 in the bottom wall and side wall of second trench 11 (i.e. in the corner of second trench 11), a channel is formed.

The above-described p-type RESURF region 4, first n-type drain region 3, second n-type drain region 8, and the edge portion of p-type base region 12 are formed in pillar section 30. The breakdown voltage is raised by forming thick insulator film 10 on the side wall of first trench 6 on pillar section 30 and by making thick insulator film 1 0 work for a field plate. Moreover, the electric field is relaxed by forming second n-type drain region 8 in the surface portion of the p-type region, that will work for p-type RESURF region 4, on the side walls of first and second trenches 6 and 11. Therefore, second n-type drain region 8 working for an n-type drain drift region can be doped more heavily at the same breakdown voltage and the ON-state resistance can be reduced. Note that the high-side N-channel TLPM is an N-channel TLPM used on the high potential side.

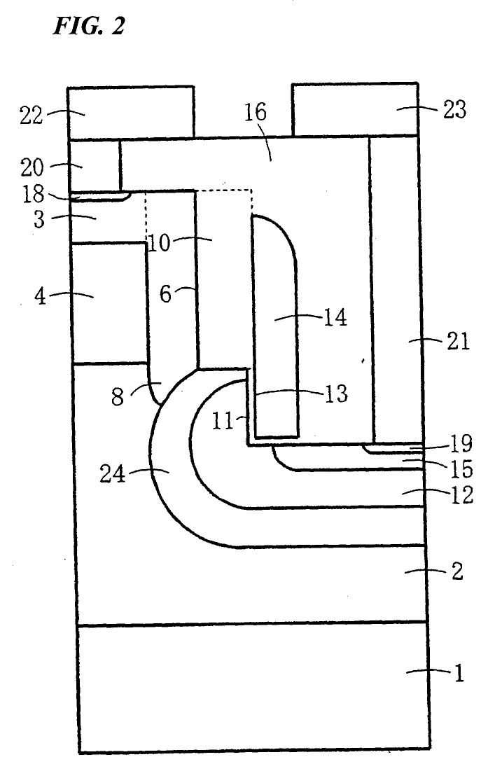

FIG. 2 is a cross sectional view of a semiconductor device according to a second embodiment of the invention. The semiconductor device shown in FIG. 2 is different from the semiconductor device shown in FIG. 1 in the following point. In FIG. 2, n-type body region 24 is formed in the bottom portion of first trench 6 such that n-type body region 24 is surrounding p-type base region 12. The impurity concentration in n-type body region 24 is set to be higher than the impurity concentration in n-type well region 2. This impurity concentration distribution is employed to prevent foreseeable punch-through that may be caused between p-type RESURF region 4 and p-type base region 12 in the structure shown in FIG. 1 from occurring. It is possible for forming an n-type body region (n-type buffer region) in the trench bottom to raise the punch-through breakdown voltage.

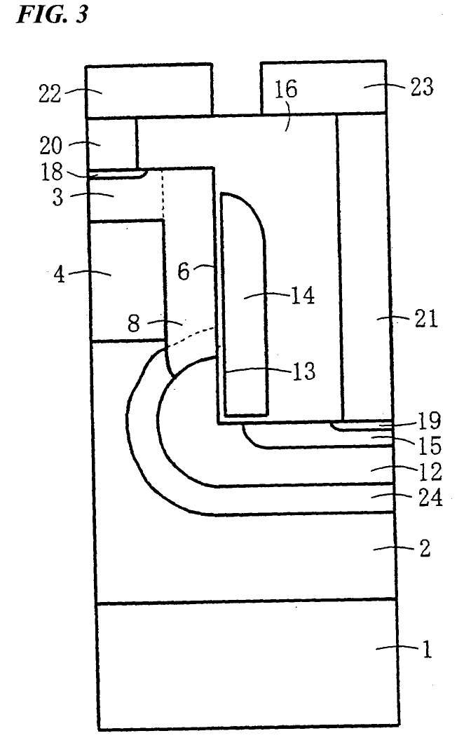

FIG. 3 is a cross sectional view of a semiconductor device according to a third embodiment of the invention. The semiconductor device shown in FIG. 3 is different from the semiconductor device shown in FIG. 2 in the following points. First, second trench 11 is not formed in FIG. 3 and the bottom of first trench 6 is positioned as deeply as the bottom of second trench 11 in FIG. 2. Second, gate insulator film 13 is formed between second drain region 8 and gate electrode 14 but thick oxide film 10 is not in FIG. 3. This structure facilitates improving the tradeoff relation between the breakdown voltage and the ON-state resistance. In FIG. 3, n-type body region 24 may not be formed with no problem in the same manner as in FIG. 1.

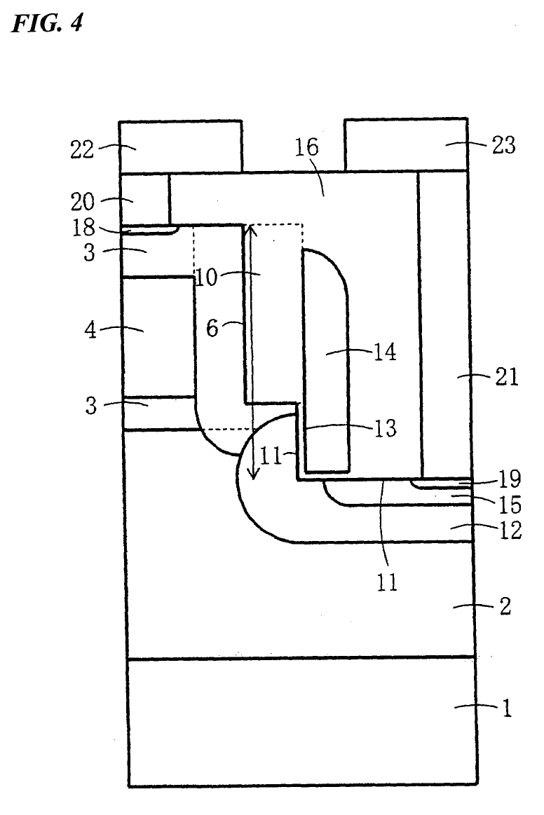

FIG. 4 is a cross sectional view of a semiconductor device according to a fourth embodiment of the invention. The semiconductor device shown in FIG. 4 is different from the semiconductor device shown in FIG. 1 in the following point. In FIG. 4, first n-type drain region 3 is formed more deeply than in FIG. 1 and p-type RESURF region 4 is formed in first n-type drain region 3. In this structure, the impurity concentration in the portion of first n-type drain region 3 under p-type RESURF region 4, namely the portion of first n-type drain region 3 located between the p-type RESURF region 4 and the n-type well region 2, is close to the impurity concentration in n-type well region 2. Therefore, the semiconductor device shown in FIG. 4 exhibits the effects similar to the effects that the semiconductor device shown in FIG. 1 exhibits.

In the semiconductor devices according to the second and third embodiments, p-type RESURF region 4 may be formed in first n-type drain region 3 with no problem. The modified semiconductor devices, include p-type RESURF region 4 formed in first n-type drain region 3, exhibit similar effects similar to the effects that the semiconductor devices according to the second and third embodiments, including p-type RESURF region 4 formed on first n-type drain region 3, exhibit.

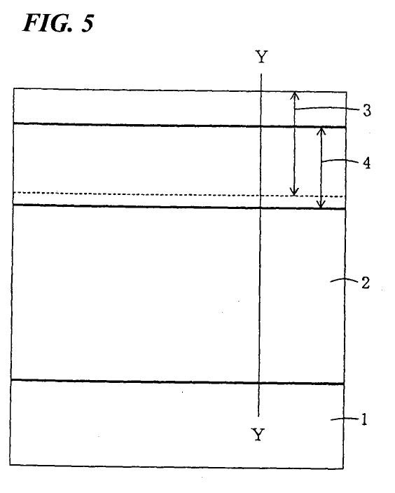

FIGS. 5 through 11 are cross sectional views for describing the manufacturing steps in a manufacturing method according to a fifth embodiment of the invention for manufacturing a semiconductor device. The manufacturing steps will be described in connection with the manufacture of the high-side N-channel TLPM shown in FIG. 1. Referring at first to FIG. 5, n-type well region 2 is formed in the entire TLPM formation region of p-type semiconductor substrate 1 by ion implantation (for example, at the dose amount of around 1×10¹³/cm² and under the acceleration voltage of around 170 keV). The implanted atoms are diffused thermally at around 1150° C. to form a junction between p-type semiconductor substrate 1 and n-type well region 2 at the depth of 4 μm.

Then, first n-type drain region 3 is formed by implanting an impurity (phosphorus atoms P31) at the dose amount of around 2×10¹³/cm² and under the acceleration voltage of around 50 keV and by diffusing the implanted impurity atoms at 1100° C. for 60 min. Then, p-type RESURF region 4 is formed by implanting impurity ions (boron atoms B11) at the dose amount of 2×10¹³/cm² and under the acceleration voltage of around 300 keV and by diffusing the implanted boron atoms at 1100° C. for 60 min. (Here, a p-type region before forming a second n-type drain region is referred to also as a “p-type RESURF region” for the sake of convenience.)

The boron ion implantation for forming p-type RESURF region 4 is conducted under an acceleration voltage higher than the acceleration voltage, under which the phosphorus ion implantation for forming first n-type drain region 3 is conducted. Although not illustrated, the technique described above facilitates setting the peak position of the implanted boron ion concentration (the net boron concentration) to be deeper than the peak position of the implanted phosphorus ion concentration (the net phosphorus concentration). By setting the peak positions of the implanted ion species as described above, p-type RESURF region 4 is formed under first n-type drain region 3 such that p-type RESURF region 4 is in contact with the bottom wall of n-type drain region 3 as the impurity distribution profile described in FIG. 12 indicates.

The order of forming first n-type drain region 3 and p-type RESURF region 4 may be reversed with no problem. It is not always necessary to form p-type RESURF region 4 under first n-type drain region 3 such that p-type RESURF region 4 is in contact with the bottom wall of first n-type drain region 3. The p-type RESURF region 4 may be formed in first n-type drain region 3 with no problem. FIG. 12 describes the impurity concentration profile along the line segment Y-Y in FIG. 5.

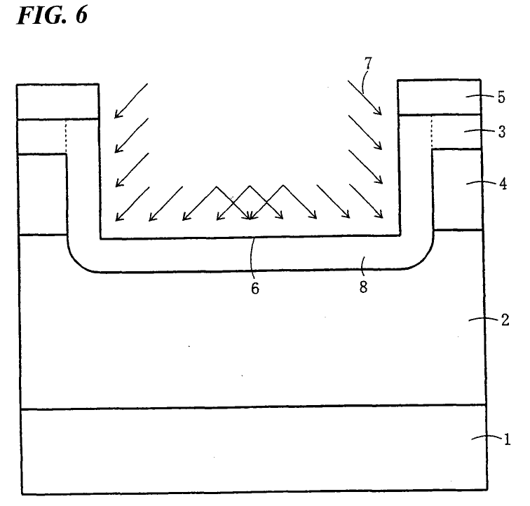

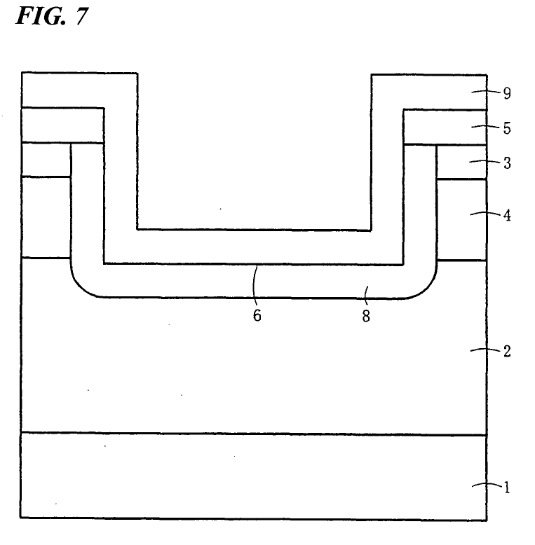

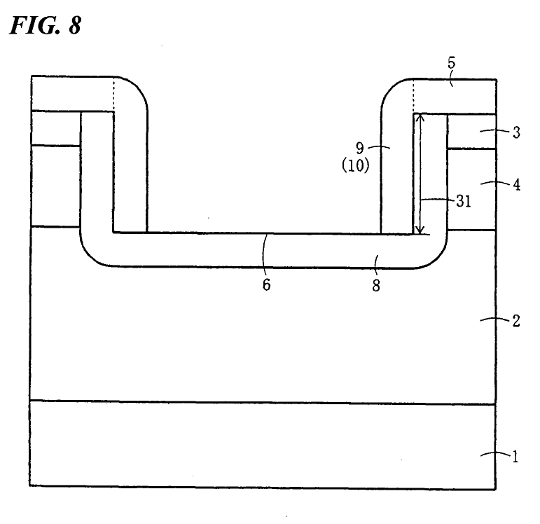

Referring now to FIG. 6, first trench mask oxide film 5 patterned is formed. First trench 6 is formed by etching using first trench mask oxide film 5 for a mask. Second n-type drain region 8 is formed in the side wall and bottom wall of first trench 6 by tilt angle ion implantation 7 using first trench mask oxide film 5 for a mask for self alignment. Even when a heavily doped region is caused below the central portion of first trench 6 by tilt angle ion implantation 7 from both sides or even when a region, to which tilt angle ion implantation 7 is not accomplished due to the shadow of first trench 6, is caused, these unintended regions will not be hazardous, since the unintended regions will be removed by forming second trench 11. The corner portions of first trench 6 are not removed by forming second trench 11. A second trench mask oxide film 9 is formed as shown in FIG. 7. Referring to FIG. 8, second trench mask oxide film 9 is left unremoved on the side walls of first trench 6 by anisotropic etching. Second trench mask oxide film 9 left unremoved will work for thick insulator film 10. Second trench mask oxide film 9 on the top of pillar section 31 is removed by the anisotropic etching. First trench mask oxide film 5 is left unremoved on the top of pillar section 31.

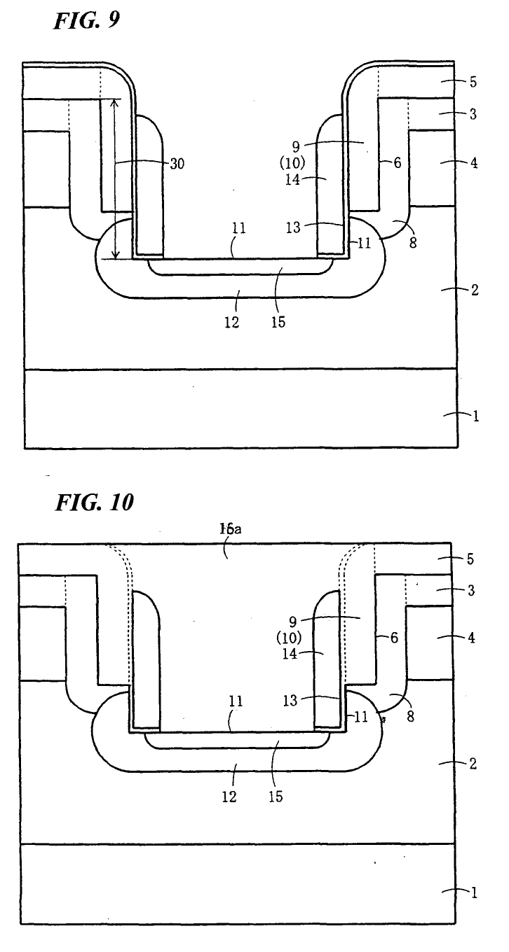

Referring now to FIG. 9, second trench 11 is formed by etching. Then, p-type base region 12 is formed by implanting boron ions into the bottom wall of second trench 11 and by thermally treating the implanted boron atoms. The p-type base region 12 is formed in the bottom wall of second trench 11 and in the lower portions of the side walls of second trench 11. Then, a gate insulator film (e.g. a gate oxide film) is formed on the side and bottom walls of second trench 11. Then, polysilicon is deposited and anisotropic etching is conducted to leave the polysilicon on the side walls of first and second trenches 6 and 11 for forming gate electrode 14 thereon. Then, n-type source region 15 is formed in the bottom of second trench 11 using the polysilicon on the side walls of first and second trenches 6 and 11 (gate electrode 14) as a mask.

Referring now to FIG. 10, first and second trenches 6 and 11 are filled with insulator film 16a (e.g. an oxide film). Referring finally to FIG. 1 1, contact holes 17 are bored through interlayer insulator film 16 formed of first trench oxide film mask 5 and insulator film 16a. In the surface portions of first drain region 3 and n-type source region 15, n-type contact regions 18 and 19 are formed, respectively. Contact holes 17 are filled with wolfram (W), resulting in wolfram plugs 20 and 21 connected respectively to n-type contact regions 18 and 19 formed in first drain region 3 and n-type source region 15. Drain metal wiring 22 and source metal wiring 23 connected respectively to wolfram plugs 20 and 21 are formed. Although not illustrated in FIG. 11, p-type base region 12 is also connected to wolfram plugs 21. The A-section in FIG. 11 is shown in the cross sectional views of the semiconductor devices according to the embodiments of the invention.

A high-side N-channel TLPM, which exhibits a high breakdown voltage and low ON-state resistance and facilitates improving the tradeoff relation between the breakdown voltage and the ON-state resistance, is manufactured through the manufacturing steps according to the invention that include a step of ion implantation for forming p-type RESURF region 4 added to the conventional manufacturing steps.

The invention has been described with reference to certain preferred embodiments thereof. It will be understood, however, that modifications and variations are possible within the scope of the appended claims.

What is claimed is:

1. A semiconductor device comprising:
a semiconductor substrate of a second conductivity type;
a well region of a first conductivity type formed in the semiconductor substrate;
a trench formed in the semiconductor substrate, wherein the trench extends from a surface of the semiconductor substrate into the well region;
a gate electrode located along a side wall of the trench and a bottom wall of the trench near the side wall thereof with a gate insulator film interposed between the gate electrode and the side wall and bottom wall of the trench;
a pillar section;
a first drain region of a first conductivity type in the pillar section;
a base region of a second conductivity type in contact with the side wall of the trench in a bottom portion thereof and the bottom wall of the trench;
a source region of the first conductivity type in a surface portion of the base region, the source region being extended to the trench through the bottom wall thereof;
a RESURF region of the second conductivity type in the pillar section, the RESURF region being formed in contact with the first drain region; and
a second drain region of the first conductivity type in a side wall surface portion of the pillar section, the second drain region being in contact with the first drain region, the base region and the RESURF region.

2. The semiconductor device according to claim 1, wherein the trench comprises a widened upper opening, and a thick oxide film interposed between the widened upper opening and the gate electrode.

3. The semiconductor device according to claim 1, a first conductivity type body region is formed in the bottom portion of trench such that the body region surrounds base region.

4. The semiconductor device according to claim 3, wherein the impurity concentration of the body region is higher than the impurity concentration in n-type well region.

5. The semiconductor device according to claim 1, wherein the trench comprises a first trench and a second trench, wherein the second trench is deeper than the first trench.

6. The semiconductor device according to claim 5, wherein the gate insulator film includes a thick insulator film located between the gate electrode and a side wall of the first trench.

7. The semiconductor device according to claim 1, wherein the RESURF region is formed in the drain region such that a portion of the drain region is located between the RESURF region and the well region.

8. The semiconductor device according to claim 1, wherein the RESUF region is formed in contact with a lower portion of the drain region and the well region.

9. A method of manufacturing a semiconductor device comprising:
forming a first conductivity type well region in a TLPM formation region of a second conductivity type substrate;
forming a first conductivity type drain region by implanting impurity atoms and diffusing the implanted impurity atoms;
forming a second conductivity type RESURF region by implanting impurity ions and diffusing the implanted impurity atoms, wherein the RESURF region is in contact with the drain region;
forming a first patterned trench mask oxide film on the surface of the semiconductor substrate;
etching a first trench in the semiconductor substrate using a first trench mask oxide film as a mask;
forming a second first conductivity type drain region in a side wall and bottom wall of first trench by tilt angle ion implantation using the first trench mask oxide film for a mask for self alignment;
forming a second patterned trench mask oxide film over the first patterned mask oxide film and the first trench;
anisotropic etching the second patterned trench mask oxide film such that the second trench mask oxide film is left unremoved on the side walls of first trench, but is removed from a top of a pillar section such that the first trench mask oxide film is left unremoved on the top of pillar section;
forming a second trench by etching to a depth deeper than the first trench;
forming a second conductivity type base region by implanting impurity atoms into a bottom wall of second trench and thermally treating the implanted impurity atoms, wherein the base region is formed in the bottom wall of second trench and in the lower portions of the side walls of second trench;
forming a gate insulator film the side and bottom walls of second trench;
forming a gate electrode on the side walls of first and second trenches;
forming a first conductivity type source region in the bottom of the second trench using the gate electrode on the side walls of first and second trenches as a mask; and
filling the first and second trenches with an insulator film.

10. A method of manufacturing a semiconductor devices as claimed in claim 9, wherein, the second conductivity type RESURF region is formed under first conductivity type drain region such that RESURF region is in contact with a bottom wall of the drain region.

11. A method of manufacturing a semiconductor devices as claimed in claim 9, wherein, the RESURF region is formed in the drain region such that a portion of the drain region is located between the RESURF region and the well region.

12. A method of manufacturing a semiconductor device as claimed in claim 9, further comprising:
forming contact holes through the first trench oxide film mask and the insulator film;
forming contact regions in surface portions of drain region and the source region through the contact holes; and
filling the contact holes with a conductive material.
